(19) United States
(12) Patent Application Publication
(10) Pub. No.: US 2026/0076234 A1
(43) Pub. Date: Mar. 12, 2026

(54) PACKAGE SUBSTRATE

(71) Applicant: SAMSUNG ELECTRONICS CO., LTD., SUWON-SI (KR)

(72) Inventor: Soon Chul LEE, Suwon-si (KR)

(21) Appl. No.: 19/210,340

(22) Filed: May 16, 2025

(30) Foreign Application Priority Data
Sep. 11, 2024 (KR) 10-2024-0123879

(51) Int. Cl. H01L 23/13

(52) U.S. Cl. CPC H10W 70/68

(57) ABSTRACT

There is provided a package substrate that improves a yield and reliability of a semiconductor package. The package substrate includes a unit area including a plurality of semiconductor chip mounting areas and a scribe lane disposed between adjacent ones of the semiconductor chip mounting areas, an edge area surrounding the unit area, and a trench formed in the edge area, the trench configured to receive a mold material for molding a semiconductor chip to be mounted on the semiconductor chip mounting area.

### CROSS-REFERENCE TO RELATED APPLICATION

This application claims priority under 35 U.S. C. § 119 to Korean Patent Application No. 10-2024-0123879, filed on Sep. 11, 2024 in the Korean Intellectual Property Office, the contents of which is herein incorporated by reference in its entirety.

### TECHNICAL FIELD

The present disclosure relates to a package substrate. More specifically, the present disclosure relates to a package substrate including a discharge trench.

### DISCUSSION OF THE RELATED ART

A semiconductor package is formed by mounting a semiconductor chip onto a package substrate. The package substrate mechanically supports the semiconductor chip and electrically connects the semiconductor chip to an external element. During a manufacturing process of the semiconductor package, a molding process is performed to protect the semiconductor chip mounted on the package substrate. The semiconductor chip is surrounded with an epoxy mold compound (EMC) during a molding process, which provides protection from external factors.

As the semiconductor chip becomes smaller, a space between the semiconductor chip and the package substrate also decreases. To fill the narrowed space, a scheme of lowering a viscosity of the epoxy mold compound (EMC) has been proposed.

However, as the viscosity of the epoxy mold compound (EMC) decreases, the epoxy mold compound (EMC) may leak out to an edge of the package substrate, thereby forming a burr. When the burr is removed from the package substrate during a subsequent process and flows into a manufacturing process apparatus, it may cause apparatus failure and deteriorate a quality of the semiconductor package.

### SUMMARY

According to an aspect of the present disclosure, there is provided a package substrate including a unit area including a plurality of semiconductor chip mounting areas and a scribe lane disposed between adjacent ones of the semiconductor chip mounting areas, an edge area surrounding the unit area, and a trench formed in the edge area, the trench configured to receive a mold material for molding a semiconductor chip to be mounted on the semiconductor chip mounting area.

According to an aspect of the present disclosure, there is provided a package substrate including a unit area including a plurality of semiconductor chip mounting areas and a scribe lane disposed between adjacent ones of the semiconductor chip mounting areas, an edge area surrounding the unit area, and a trench formed in the edge area, wherein the edge area includes different first and second edges, wherein the trench includes a first trench disposed between the unit area and the first edge, and a second trench disposed between the unit area and the second edge, wherein a depth of the second trench is greater than a depth of the first trench.

According to an aspect of the present disclosure, there is provided a package substrate including a unit area including a plurality of semiconductor chip mounting areas and a scribe lane disposed between adjacent ones of the semiconductor chip mounting areas, an edge area surrounding the unit area, a trench formed in the edge area, and configured to receive a mold material for molding a semiconductor chip to be mounted on the semiconductor chip mounting area, and a discharge trench formed in the edge area and configured to discharge the mold material in the trench to an outside of the package substrate, wherein the discharge trench includes first and second discharge trenches, wherein the edge area includes a first edge and a third edge disposed opposite to each other, a second edge intersecting the first edge and the third edge, a first corner at which the first edge and the second edge intersect each other, and a second corner at which the second edge and the third edge intersect each other, wherein the trench includes first and second portions extending in a parallel manner to the first edge, and connected to the discharge trench, wherein the first portion close to the second edge and the second portion is far away from the second edge, wherein the first discharge trench extends from the first portion of the trench toward the first corner, wherein the second discharge trench extends from the second portion of the trench toward the second corner, wherein each of a bottom surface of the trench and a bottom surface of the discharge trench is inclined.

It should be noted that the effects of the present disclosure are not necessarily limited to those described above, and other effects of the present disclosure will be apparent from the following description.

### BRIEF DESCRIPTION OF DRAWINGS

The above and other aspects and features of the present disclosure will become more apparent by describing in detail illustrative embodiments thereof with reference to the attached drawings, in which:

FIG. 1 is a schematic conceptual diagram for illustrating a package substrate according to embodiments of the present inventive concept.

FIG. 2 is a plan view of the package substrate of FIG. 1.

FIG. 3 is a cross-sectional view as taken along a line A-A of FIG. 1.

FIG. 4 is a cross-sectional view as taken along a line B-B of FIG. 1.

FIG. 5 is a cross-sectional view as taken along a line C-C of FIG. 1.

FIGS. 6 and 7 are diagrams for illustrating an effect of the package substrate of FIG. 1.

FIG. 8 is a diagram for illustrating a package substrate according to embodiments of the present inventive concept.

FIG. 9 is a diagram for illustrating a package substrate according to embodiments of the present inventive concept.

FIGS. 10, 11, 12, and 13 are diagrams for illustrating a package substrate according to embodiments of the present inventive concept.

FIG. 14 is a diagram for illustrating a package substrate according to embodiments of the present inventive concept.

FIGS. 15, 16, 17, and 18 are diagrams for illustrating a package substrate according to embodiments of the present inventive concept.

### DETAILED DESCRIPTIONS

Although terms such as first, second, upper, and lower are used herein to describe various elements or components, it is obvious that these element or components are not limited by the terms. Rather, the terms are merely used herein to distinguish one element or component from another element or component. Therefore, it is obvious that a first element or component as mentioned below may also be a second element or component within the technical spirit of the present disclosure. Further, it is obvious that a lower element or component as mentioned below may also be an upper element or component within the technical spirit of the present disclosure.

In conventional methods, mold material may flow to the package substrate sidewall and form a burr. The burr may fall from the package substrate and flow into the semiconductor process apparatus, which may lead to operation failure or reduced productivity of the semiconductor package.

According to embodiments of the present inventive concept, trenches may be disposed in an edge area of the package substrate, where the semiconductor chip is not mounted. The trenches may receive mold material flowing out during the manufacturing process of the semiconductor package.

Furthermore, discharge trenches may discharge the mold material outside of the package substrate. To discharge the mold material, a bottom surface of the trench and a bottom surface of the discharge trench may be inclined.

As a result, trenches and discharge trenches may prevent a formation of the burr, increasing a yield and reliability of the semiconductor package.

Hereinafter, embodiments according to the technical idea of the present inventive concept are described with reference to the attached drawings.

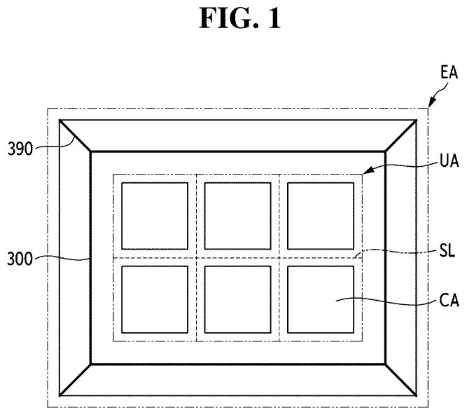

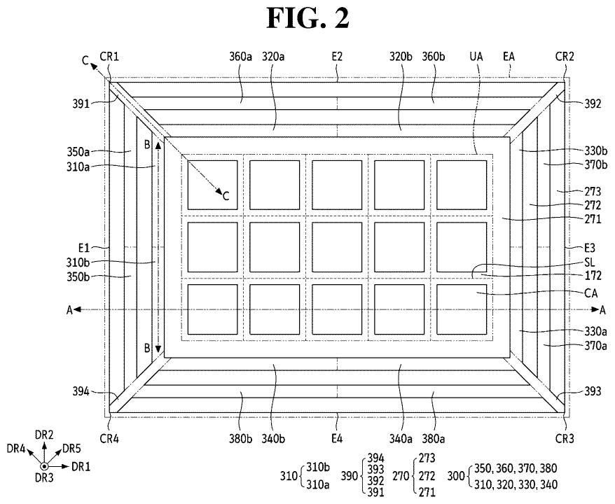

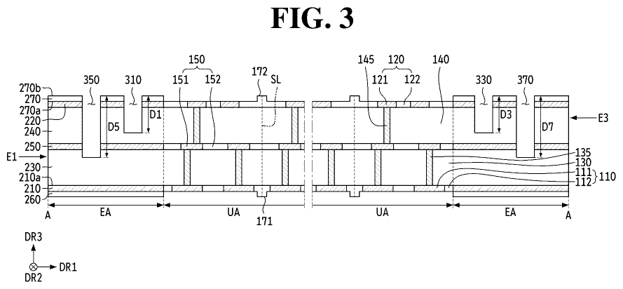

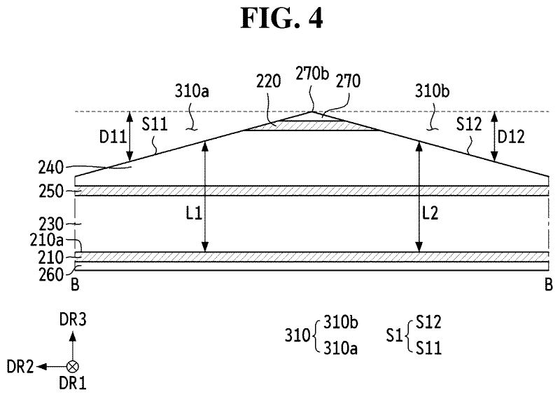

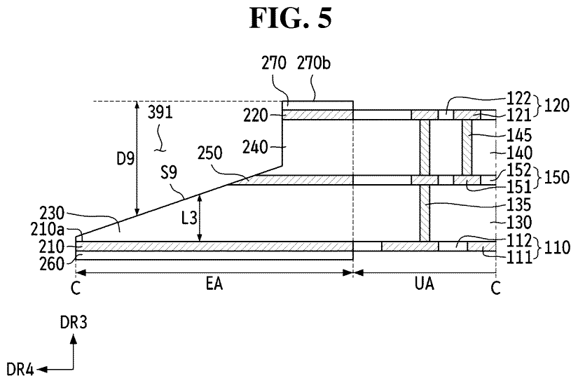

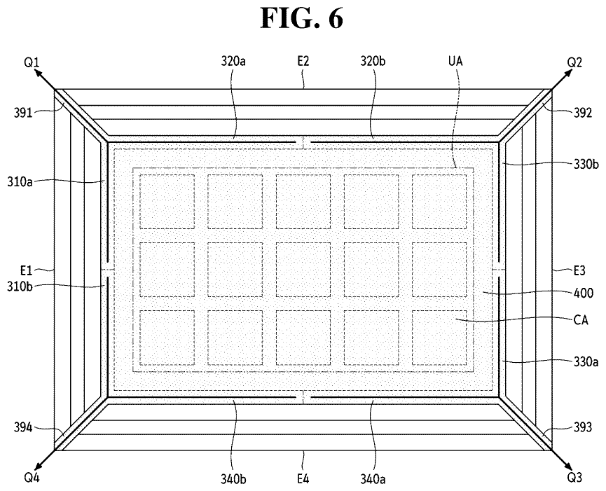

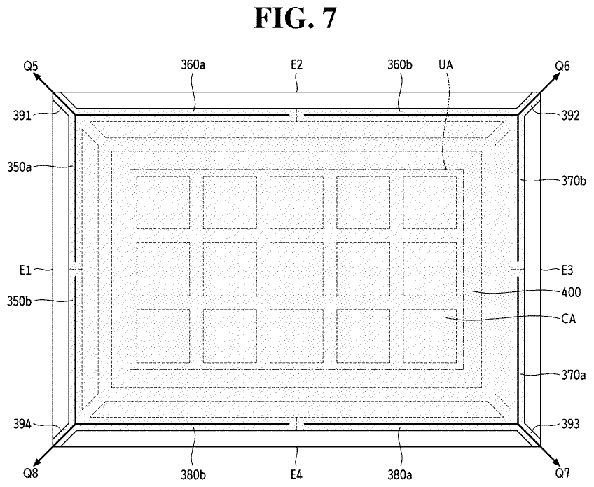

FIG. 1 is a schematic conceptual diagram for illustrating a package substrate according to embodiments of the present inventive concept. FIG. 2 is a plan view of the package substrate of FIG. 1. FIG. 3 is a cross-sectional view as taken along a line A-A of FIG. 1. FIG. 4 is a cross-sectional view as taken along a line B-B of FIG. 1. FIG. 5 is a cross-sectional view as taken along a line C-C of FIG. 1. FIG. 6 and FIG. 7 are diagrams for illustrating an effect of the package substrate of FIG. 1.

First, referring to FIGS. 1 to 5, the package substrate according to embodiments of the present inventive concept may include a unit area UA, an edge area EA, a trench 300, and a discharge trench 390.

The unit area UA may extend in a first direction DR1 and a second direction DR2. The unit area UA may be a central area of the package substrate in a plan view. The unit area UA may include a plurality of semiconductor chip mounting areas CA and scribe lanes SL.

The plurality of semiconductor chip mounting areas CA may be arranged along the first direction DR1 and the second direction DR2. The semiconductor chip mounting areas CA may be spaced apart from each other. Each semiconductor chip mounting area CA may be an area where a semiconductor chip is to be mounted.

The scribe lane SL may be disposed between adjacent semiconductor chip mounting areas CA. The scribe lane SL may extend in the first direction DR1 and the second direction DR2. The scribe lane SL may extend in a third direction DR3, which intersects the first direction DR1 and the second direction DR2. The scribe lane SL may be formed to indicate a portion of the package substrate along which the package substrate is to be cut. The package substrate may be cut along the scribe lanes SL such that the plurality of semiconductor chip mounting areas CA may be individually separated from each other.

The unit area UA may include a first unit wiring layer 110, a second unit wiring layer 120, a third unit wiring layer 150, a first unit insulating layer 130, a second unit insulating layer 140, a first through-via 135, a second through-via 145, a first unit protective layer 171, and a second unit protective layer 172.

The first unit wiring layer 110 may extend in the first direction DR1 and the second direction DR2. The first unit wiring layer 110 may include a plurality of first unit wirings 111 and a first wiring protective layer 112.

The plurality of first unit wirings 111 may be spaced apart from each other in the first direction DR1. The plurality of first unit wirings 111 may be spaced apart from each other in a fourth direction DR4, which is between the first direction DR1 and the second direction DR2. The first unit wiring 111 may include copper (Cu).

The first wiring protective layer 112 may fill a space between adjacent first unit wirings 111. For example, the first wiring protective layer 112 may be disposed between the plurality of first unit wirings 111. The first wiring protective layer 112 may be a solder resist. The first wiring protective layer 112 may include, for example, an epoxy resin.

The second unit wiring layer 120 may be disposed on the first unit wiring layer 110. The second unit wiring layer 120 may extend in the first direction DR1 and the second direction DR2. The second unit wiring layer 120 may include a plurality of second unit wirings 121 and a second wiring protective layer 122.

The plurality of second unit wirings 121 may be spaced apart from each other in the first direction DR1. The plurality of second unit wirings 121 may be spaced apart from each other in the fourth direction DR4. The second unit wirings 121 may include copper (Cu).

The second wiring protective layer 122 may fill a space between adjacent second unit wirings 121. For example, the second wiring protective layer 122 may be disposed between the plurality of second unit wirings 121. The second wiring protective layer 122 may be a solder resist. The second wiring protective layer 122 may include the same material as that of the first wiring protective layer 112. For example, the second wiring protective layer 122 may include an epoxy resin.

A length of the first unit wiring 111 in the first direction DR1 may be greater than a length of the second unit wiring 121 in the first direction DR1. A length of the first unit wiring 111 in the fourth direction DR4 may be greater than a length of the second unit wiring 121 in the fourth direction DR4. The second unit wiring 121 may be connected to a micro bump attached to the semiconductor chip. To electrically connect the miniaturized semiconductor chip to an external element, a length of the second unit wiring 121 may be greater than a length of the first unit wiring 111.

The third unit wiring layer 150 may be disposed between the first unit wiring layer 110 and the second unit wiring layer 120. For example, the third unit wiring layer 150 may be disposed below the second unit wiring layer 120 and above the first unit wiring layer 110.

The third unit wiring layer 150 may extend in the first direction DR1 and the second direction DR2. The third unit wiring layer 150 may include a plurality of third unit wirings 151 and a third unit interlayer insulating film 152.

The plurality of third unit wirings 151 may be spaced apart from each other in the first direction DR1. The plurality of third unit wirings 151 may be spaced apart from each other in the fourth direction DR4. The third unit wiring 151 may include copper (Cu).

The third unit interlayer insulating film 152 may fill a space between adjacent third unit wirings 151. For example, the third unit interlayer insulating film 152 may be disposed between the plurality of third unit wirings 151. The third unit interlayer insulating film 152 may be a prepreg. The third unit interlayer insulating film 152 may include a material different from that of each of the first wiring protective layer 112 and the second wiring protective layer 122. The third unit interlayer insulating film 152 may include, for example, glass fiber.

The first unit insulating layer 130 may be disposed on the first unit wiring layer 110. For example, the first unit insulating layer 130 may cover top surface of the plurality of first unit wirings 111 and the first wiring protective layer 112. The first unit insulating layer 130 may be deposited on the first unit wiring layer 110. The first unit insulating layer 130 may be disposed between the first unit wiring layer 110 and the third unit wiring layer 150. The first unit insulating layer 130 may extend in the first direction DR1 and the second direction DR2.

A thickness of the first unit insulating layer 130 measured in the third direction DR3 may be greater than a thickness of the first unit wiring layer 110 measured in the third direction DR3. The third direction DR3 is a direction intersecting the first direction DR1 and the second direction DR2. The third direction DR3 may be a thickness direction of the package substrate.

The first unit insulating layer 130 may be in contact with the third unit interlayer insulating film 152. For example, the third unit interlayer insulating film 152 may be disposed on an upper surface of the first unit insulating layer 130. A boundary between the first unit insulating layer 130 and the third unit interlayer insulating film 152 is illustrated as being defined. However, embodiments of the present disclosure are not necessarily limited thereto. In example embodiments of the present inventive concept, the boundary between the first unit insulating layer 130 and the third unit interlayer insulating film 152 might not be defined. The first unit insulating layer 130 may include glass fiber.

The second unit insulating layer 140 may be disposed on the third unit wiring layer 150. For example, the second unit insulating layer 140 may cover top surfaces of the plurality of third unit wirings 151 and the third interlayer insulating film 152. The second unit insulating layer 140 may be deposited on the third unit wiring layer 150. The second unit insulating layer 140 may be disposed between the second unit wiring layer 120 and the third unit wiring layer 150. The second unit insulating layer 140 may extend in the first direction DR1 and the second direction DR2.

A thickness of the second unit insulating layer 140 measured in the third direction DR3 may be greater than the thickness of the first unit wiring layer 110 measured in the third direction DR3. The thickness of the second unit insulating layer 140 in the third direction DR3 may be greater than the thickness of the second unit wiring layer 120 in the third direction DR3.

The second unit insulating layer 140 may contact the third unit interlayer insulating film 152. For example, the third unit interlayer insulating film 152 may be disposed on a bottom surface of the second unit insulating layer 140. A boundary between the second unit insulating layer 140 and the third unit interlayer insulating film 152 is illustrated as being defined. However, embodiments of the present disclosure are not necessarily limited thereto. In example embodiments of the present inventive concept, the boundary between the second unit insulating layer 140 and the third unit interlayer insulating film 152 might not be defined.

The second unit insulating layer 140 may include the same material as that of the first unit insulating layer 130. For example, the second unit insulating layer 140 may include glass fiber.

The first through-via 135 may be disposed within the first unit insulating layer 130. The first through-via 135 may extend in the third direction DR3. The first through-via 135 may extend through the first unit insulating layer 130 so as to be connected to the first unit wiring 111 and the third unit wiring 151. The first through-via 135 may electrically connect the first unit wiring 111 and the third unit wiring 151 to each other.

The second through-via 145 may be disposed within the second unit insulating layer 140. The second through-via 145 may extend in the third direction DR3. The second through-via 145 may extend through the second unit insulating layer 140 so as to be connected to the second unit wiring 121 and the third unit wiring 151. The second through-via 145 may electrically connect the second unit wiring 121 and the third unit wiring 151 to each other.

The first through-via 135 and the second through-via 145 may include the same material. Each of the first through-via 135 and the second through-via 145 may include, for example, copper (Cu).

The first unit protective layer 171 may be disposed on the first unit wiring layer 110. The first unit protective layer 171 may be disposed on the first wiring protective layer 112. The first unit protective layer 171 may protrude from the first unit wiring layer 110 along the third direction DR3. The first unit protective layer 171 may include the same material as that of the first wiring protective layer 112. For example, the first unit protective layer 171 may include an epoxy resin

The second unit protective layer 172 may be disposed on the second unit wiring layer 120. The second unit protective layer 172 may be disposed on the second wiring protective layer 122. The second unit protective layer 172 may be disposed between adjacent semiconductor chip mounting areas CA. For example, the second unit protective layer 172 may be disposed adjacent to the scribe lane SL. The second unit protective layer 172 may protrude from the second unit wiring layer 120 along the third direction DR3. The second unit protective layer 172 may overlap the first unit protective layer 171 in the third direction DR3.

The second unit protective layer 172 may be in contact with the second wiring protective layer 122. The second unit protective layer 172 may include the same material as that of the second wiring protective layer 122. The second unit protective layer 172 may be, for example, solder resist.

The scribe lane SL may be positioned on the second unit protective layer 172. For example, the scribe lane SL may extend between the first unit protective layer and the second unit protective layer 172 along the third direction DR3. The second unit protective layer 172 may be removed during a process of separating the adjacent semiconductor chip mounting areas CA from each other by cutting the package substrate along the scribe lane SL.

The edge area EA may surround the unit area UA. The edge area EA may extend in the first direction DR1. The edge area EA may extend in the second direction DR2.

The edge area EA may include a first edge wiring 210, a second edge wiring 220, a third edge wiring 250, a first edge insulating layer 230, a second edge insulating layer 240, a first edge protective layer 260, and a second edge protective layer 270.

The first edge wiring 210 may extend from the first unit wiring layer 110 in the first direction DR1 and the second direction DR2. The first edge wiring 210 may overlap the first unit wiring layer 110 in the first direction DR1. The first edge wiring 210 may overlap the first unit wiring layer 110 in the fourth direction DR4.

The second edge wiring 220 may be disposed on the first edge wiring 210. The second edge wiring 220 may extend from the second unit wiring layer 120 in the first direction DR1 and the second direction DR2. The second edge wiring 220 may overlap the second unit wiring layer 120 in the first direction DR1. The second edge wiring 220 may overlap the second unit wiring layer 120 in the fourth direction DR4.

The third edge wiring 250 may be disposed on the first edge wiring 210. The third edge wiring 250 may be disposed between the first edge wiring 210 and the second edge wiring 220. The third edge wiring 250 may extend from the third unit wiring layer 150 in the first direction DR1 and the second direction DR2. The third edge wiring 250 may overlap the second unit wiring layer 120 in the first direction DR1. The third edge wiring 250 may overlap the third unit wiring layer 150 in the fourth direction DR4.

A thickness of the third edge wiring 250 measured in the third direction DR3 may be equal to the thickness of the third unit wiring 151 measured in the third direction DR3.

Each of the first edge wiring 210, the second edge wiring 220, and the third edge wiring 250 may include copper (Cu).

The first edge insulating layer 230 may be disposed on the first edge wiring 210. The first edge insulating layer 230 may be disposed between the first edge wiring 210 and the third edge wiring 250. The first edge insulating layer 230 may extend from the first unit insulating layer 130 in the first direction DR1 and the second direction DR2. The first edge insulating layer 230 may overlap the first unit insulating layer 130 in the first direction DR1. The first edge insulating layer 230 may overlap the first unit insulating layer 130 in the fourth direction DR4.

The first edge insulating layer 230 may contact the first edge wiring 210. The first edge wiring 210 may include a contact surface 210a that contacts the first edge insulating layer 230. For example, the contact surface 210a may be an upper surface of the first edge wiring 210 and a bottom surface of the first edge insulating layer 230.

The first edge insulating layer 230 may contact the first unit insulating layer 130. A boundary between the first edge insulating layer 230 and the first unit insulating layer 130 might not be defined. The first edge insulating layer 230 may include the same material as that of the first unit insulating layer 130. For example, the first edge insulating layer 230 may include glass fiber.

A thickness of the first edge insulating layer 230 measured in the third direction DR3 may be equal to the thickness of the first unit insulating layer 130 measured in the third direction DR3.

The second edge insulating layer 240 may be disposed on the third edge wiring 250. The second edge insulating layer 240 may be disposed between the second edge wiring 220 and the third edge wiring 250. The second edge insulating layer 240 may extend from the second unit insulating layer 140 in the first direction DR1 and the second direction DR2. The second edge insulating layer 240 may overlap the second unit insulating layer 140 in the first direction DR1. The second edge insulating layer 240 may overlap the second unit insulating layer 140 in the fourth direction DR4.

The second edge insulating layer 240 may be in contact with the second unit insulating layer 140. The boundary between the second edge insulating layer 240 and the second unit insulating layer 140 might not defined. The second edge insulating layer 240 may include the same material as that of the second unit insulating layer 140. For example, the second edge insulating layer 240 may include glass fiber.

A thickness of the second edge insulating layer 240 measured in the third direction DR3 may be equal to the thickness of the second unit insulating layer 140 measured in the third direction DR3.

The first edge protective layer 260 may be disposed on the first edge wiring 210. For example, the first edge protective layer 260 may be disposed on a bottom surface of the first edge wiring 210. The first edge wiring 210 may be disposed between the first edge protective layer 260 and the first edge insulating layer 230.

The second edge protective layer 270 may be disposed on the second edge wiring 220. For example, the second edge protective layer 270 may be disposed on an upper surface of the second edge wiring 220. The second edge wiring 220 may be disposed between the second edge protective layer 270 and the second edge insulating layer 240. The second edge protective layer 270 may cover the upper surface of the second edge wiring 220. The second edge protective layer 270 may overlap the second unit protective layer 172 in the first direction DR1. The second edge protective layer 270 might not overlap the second unit wiring in the first direction DR1. The second edge protective layer 270 may include the same material as that of the second unit protective layer 172.

The second edge protective layer 270 may be in contact with the second edge wiring 220. The second edge protective layer 270 may include a first surface 270a and a second surface 270b that are disposed opposite to each other in the third direction DR3. The first surface 270a may be in contact with the second edge wiring 220.

The edge area EA may include a first edge E1 and a third edge E3 that are disposed opposite to each other in the first direction DR1. The edge area EA may include a second edge E2 and a fourth edge E4 that are opposite to each other in the second direction DR2. The first edge E1, the second edge E2, the third edge E3, and the fourth edge E4 may define a side surface of the package substrate. For example, the first edge E1, the second edge E2, the third edge E3, and the fourth edge E4 may be disposed so as to surround the plurality of semiconductor chip mounting areas CA and scribe lanes SL.

A length of the first edge E1 may be smaller than a length of the second edge E2. The length of the first edge E1 may be smaller than a length of the fourth edge E4. A length of the third edge E3 may be smaller than the length of the second edge E2. The length of the third edge E3 may be smaller than the length of the fourth edge E4.

The trench 300 is formed in the edge area EA. The trench 300 may extend from the second surface 270b of the second edge protective layer 270 along the third direction DR3. The trench 300 may expose the second edge wiring 220. The trench 300 may expose the second edge insulating layer 240. For example, side surfaces of the second edge wiring 220 and the second edge insulating layer 240 may be exposed due to the trench 300.

As used herein, a depth of the trench 300 means a distance from a top opening of the trench 300 to a bottom surface of the trench 300. For example, the depth of the trench 300 means a length of the trench 300 measured in the third direction DR3. For example, the depth of the trench 300 means a distance from the second surface 270b of the second edge protective layer 270 to the bottom surface of the trench 300, depending on where the trench 300 ends. A width of the trench 300 means a length of the trench 300 measured in the first direction DR1.

The trench 300 may include a first trench 310, a second trench 320, a third trench 330, a fourth trench 340, a fifth trench 350, a sixth trench 360, a seventh trench 370, and an eighth trench 380.

The first trench 310 may be disposed in the edge area EA, between the unit area UA and the first edge E1. The first trench 310 may be disposed adjacent to and extend in a parallel manner to the first edge E1. The first trench 310 may extend in the second direction DR2. A bottom surface S1 of the first trench may be inclined in a cross-sectional view, cut in the longitudinal direction (e.g., in the second direction DR2) of the first trench 310. The first trench 310 may include a first portion 310a disposed close to the second edge E2 and a second portion 310b disposed far from the second edge E2.

Referring to FIG. 2 and FIG. 4, a bottom surface S11 of the first portion 310a of the first trench 310 may be inclined. A depth D11 of the first portion 310a of the first trench 310 may increase as it extends toward the second edge E2. A first distance L1 refers to a distance measured in the third direction DR3 from the contact surface 210a of the first edge wiring 210 to the bottom surface S11 of the first portion 310a of the first trench 310. The first distance L1 may decrease as the bottom surface S11 extends toward the second edge E2.

A bottom surface S12 of the second portion 310b of the first trench 310 may be inclined. A depth D12 of the second portion 310b of the first trench 310 may increase as it extends toward the fourth edge E4. The second distance L2 refers to a distance measured in the third direction DR3 from the contact surface 210a of the first edge wiring 210 to the bottom surface S12 of the second portion 310b of the first trench 310. The second distance L2 may decrease as the bottom surface S12 extends toward the fourth edge E4.

The bottom surface S11 of the first portion 310a of the first trench 310 and the bottom surface S12 of the second portion 310b of the first trench 310 may be connected to each other.

The second trench 320 may be disposed between the unit area UA and the second edge E2. The second trench 320 may be disposed adjacent to and extend in a parallel manner to the second edge E2. The second trench 320 may extend in the first direction DR1. In a cross-sectional view cut in the longitudinal direction (for example, in the first direction DR1) of the second trench 320, a bottom surface of the second trench 320 may be inclined. The second trench 320 may include a first portion 320a close to the first edge E1 and a second portion 320b far from the first edge E1.

A bottom surface of the first portion 320a of the second trench 320 may be inclined. A depth of the first portion 320a of the second trench 320 may increase as it extends toward the first edge E1. A bottom surface of the second portion 320b of the second trench 320 may be inclined. A depth of the second portion 320b of the second trench 320 may increase as it extends toward the third edge E3. The bottom surface of the first portion 320a of the second trench 320 may be connected to the bottom surface of the second portion 320b of the second trench 320.

The third trench 330 may be disposed between the unit area UA and the third edge E3. The third trench 330 may be disposed adjacent to and extend in a parallel manner to the third edge E3. The third trench 330 may extend in the second direction DR2. In a cross-sectional view cut along the longitudinal direction (for example, in the second direction DR2) of the third trench 330, a bottom surface of the third trench 330 may be inclined. The third trench 330 may include a first portion 330a close to the fourth edge E4 and a second portion 330b far from the fourth edge E4.

A bottom surface of the first portion 330a of the third trench 330 may be inclined. A depth of the first portion 330a of the third trench 330 may increase as it extends toward the fourth edge E4. A bottom surface of the second portion 330b of the third trench 330 may be inclined. A depth of the second portion 330b of the third trench 330 may increase as it extends toward the second edge E2. The bottom surface of the first portion 330a of the third trench 330 may be connected to the bottom surface of the second portion 330b of the third trench 330.

The fourth trench 340 may be disposed between the unit area UA and the fourth edge E4. The fourth trench 340 may be disposed adjacent to and extend in a parallel manner to the fourth edge E4. The fourth trench 340 may extend in the first direction DR1. In a cross-sectional view, cut in the longitudinal direction (for example, in the first direction DR1) of the fourth trench 340, a bottom surface of the fourth trench 340 may be inclined. The fourth trench 340 may include a first portion 340a close to the third edge E3 and a second portion 340b far from the third edge E3.

A bottom surface of the first portion 340a of the fourth trench 340 may be inclined. A depth of the first portion 340a of the fourth trench 340 may increase as it extends toward the third edge E3. A bottom surface of the second portion 340b of the fourth trench 340 may be inclined. A depth of the second portion 340b of the fourth trench 340 may increase as it extends toward the first edge E1. The bottom surface of the first portion 340a of the fourth trench 340 may be connected to the bottom surface of the second portion 340b of the fourth trench 340.

The fifth trench 350 may be disposed between the unit area UA and the first edge E1. The fifth trench 350 may be disposed between the first edge E1 and the first trench 310. The fifth trench 350 may be spaced apart from the first trench 310 in the first direction DR1. The fifth trench 350 may be disposed closer to the first edge E1 than the first trench 310. The fifth trench 350 may be disposed further away from the unit area UA than the first trench 310.

The fifth trench 350 may be disposed adjacent to and extend in a parallel manner to the first edge E1. The fifth trench 350 may extend in the second direction DR2. In a cross-sectional view cut in the longitudinal direction (for example, in the second direction DR2) of the fifth trench 350, a bottom surface of the fifth trench 350 may be inclined. The fifth trench 350 may include a first portion 350a disposed close to the second edge E2 and a second portion 350b disposed far from the second edge E2.

A bottom surface of the first portion 350a of the fifth trench 350 may be inclined. A depth of the first portion 350a of the fifth trench 350 may increase as it extends toward the second edge E2. A bottom surface of the second portion 350b of the fifth trench 350 may be inclined. A depth of the second portion 350b of the fifth trench 350 may increase as it extends toward the fourth edge E4. The bottom surface of the first portion 350a of the fifth trench 350 may be connected to the bottom surface of the second portion 350b of the fifth trench 350.

The sixth trench 360 may be disposed between the unit area UA and the second edge E2. The sixth trench 360 may be disposed between the second edge E2 and the second trench 320. The sixth trench 360 may be spaced apart from the second trench 320 in the second direction DR2. The sixth trench 360 may be disposed closer to the second edge E2 than the second trench 320. The sixth trench 360 may be disposed further away from the unit area UA than the second trench 320.

The sixth trench 360 may be disposed adjacent to and extend in a parallel manner to the second edge E2. The sixth trench 360 may extend in the first direction DR1. In a cross-sectional view cut in the longitudinal direction (for example, in the first direction DR1) of the sixth trench 360, a bottom surface of the sixth trench 360 may be inclined. The sixth trench 360 may include a first portion 360a close to the first edge E1 and a second portion 360b far from the first edge E1.

A bottom surface of the first portion 360a of the sixth trench 360 may be inclined. A depth of the first portion 360a of the sixth trench 360 may increase as it extends toward the first edge E1. A bottom surface of the second portion 360b of the sixth trench 360 may be inclined. A depth of the second portion 360b of the sixth trench 360 may increase as it extends toward the third edge E3. The bottom surface of the first portion 360a of the sixth trench 360 may be connected to the bottom surface of the second portion 360b of the sixth trench 360.

The seventh trench 370 may be disposed between the unit area UA and the third edge E3. The seventh trench 370 may be disposed between the third edge E3 and the third trench 330. The seventh trench 370 may be spaced apart from the third trench 330 in the first direction DR1. The seventh trench 370 may be disposed closer to the third edge E3 than the third trench 330. The seventh trench 370 may be disposed further away from the unit area UA than the third trench 330.

The seventh trench 370 may be disposed adjacent to and extend in a parallel manner to the third edge E3. The seventh trench 370 may extend in the second direction DR2. In a cross-sectional view cut in the longitudinal direction (for example, in the second direction DR2) of the seventh trench 370, a bottom surface of the seventh trench 370 may be inclined. The seventh trench 370 may include a first portion 370a close to the fourth edge E4 and a second portion 370b far from the fourth edge E4.

A bottom surface of the first portion 370a of the seventh trench 370 may be inclined. A depth of the first portion 370a of the seventh trench 370 may increase as it extends toward the fourth edge E4. A bottom surface of the second portion 370b of the seventh trench 370 may be inclined. A depth of the second portion 370b of the seventh trench 370 may increase as it extends toward the second edge E2. The bottom surface of the first portion 370a of the seventh trench 370 may be connected to the bottom surface of the second portion 370b of the seventh trench 370.

The eighth trench 380 may be disposed adjacent to and extend in a parallel manner to the fourth edge E4. The eighth trench 380 may be disposed between the unit area UA and the fourth edge E4. The eighth trench 380 may be disposed between the fourth edge E4 and the fourth trench 340. The eighth trench 380 may be spaced apart from the fourth trench 340 in the second direction DR2. The eighth trench 380 may be disposed closer to the fourth edge E4 than the fourth trench 340. The eighth trench 380 may be disposed further away from the unit area UA than the fourth trench 340.

The eighth trench 380 may extend in the first direction DR1. In a cross-sectional view cut in the longitudinal direction (for example, in the first direction DR1) of the eighth trench 380, a bottom surface of the eighth trench 380 may be inclined. The eighth trench 380 may include a first portion 380a close to the fourth edge E4 and a second portion 380b far from the fourth edge E4.

A bottom surface of the first portion 380a of the eighth trench 380 may be inclined. A depth of the first portion 380a of the eighth trench 380 may increase as it extends toward the third edge E3. A bottom surface of the second portion 380b of the eighth trench 380 may be inclined. A depth of the second portion 380b of the eighth trench 380 may increase as it extends toward the first edge E1. The bottom surface of the first portion 380a of the eighth trench 380 may be connected to the bottom surface of the second portion 380b of the eighth trench 380.

Referring to FIG. 3, a depth D1 of the first trench 310 may be smaller than a depth D5 of the fifth trench 350. The depth D1 of the first trench 310 may be smaller than a depth D7 of the seventh trench 370. The depth D1 of the first trench 310 may be equal to a depth D3 of the third trench 330. The depth D3 of the third trench 330 may be smaller than the depth D5 of the fifth trench 350. The depth D3 of the third trench 330 may be smaller than the depth D7 of the seventh trench 370.

The edge area EA may include a first corner CR1, a second corner CR2, a third corner CR3, and a fourth corner CR4.

The first corner CR1 may be defined by the first edge E1 and the second edge E2. The first corner CR1 may be a portion where the first edge E1 and the second edge E2 intersect each other. The second corner CR2 may be defined by the second edge E2 and the third edge E3. The second corner CR2 may be a portion where the second edge E2 and the third edge E3 intersect each other. The third corner CR3 may be defined by the third edge E3 and the fourth edge E4. The third corner CR3 may be a portion where the third edge E3 and the fourth edge E4 intersect each other. The fourth corner CR4 may be defined by the first edge E1 and the fourth edge E4. The fourth corner CR4 may be a portion where the first edge E1 and the fourth edge E4 intersect each other.

The discharge trench 390 may be formed in the edge area EA. The discharge trench 390 may be disposed between the corner of the unit area UA and the corner of the edge area EA. The discharge trench 390 may be connected to the trench 300. The discharge trench 390 may extend from the trench 300 toward the corner of the edge area EA. The discharge trench 390 may be connected to at least some trenches 300 of the first to eighth trenches 310 to 380. A bottom surface of the discharge trench 390 may be inclined.

The discharge trench 390 may include a first discharge trench 391, a second discharge trench 392, a third discharge trench 393, and a fourth discharge trench 394.

The first discharge trench 391 may be disposed between the unit area UA and the first corner CR1. The first discharge trench 391 may extend toward the first corner CR1. The first discharge trench 391 may extend in the fourth direction DR4, which is between the first direction DR1 and the second direction DR2.

The first discharge trench 391 may be connected to the first portion 310a of the first trench 310. The first discharge trench 391 may be connected to the first portion 320a of the second trench 320. The first discharge trench 391 may be connected to the first portion 350a of the fifth trench. The first discharge trench 391 may be connected to the first portion 360a of the sixth trench.

Referring to FIG. 2 and FIG. 5, a bottom surface S9 of the first discharge trench 391 may be inclined. A depth D9 of the first discharge trench 391 may increase as the first discharge trench 391 extends toward the first corner CR1. A third distance L3 may decrease as the first discharge trench 391 extends toward the first corner CR1. The third distance L3 refers to a distance measured from the contact surface 210a of the first edge wiring 210 to the bottom surface S9 of the first discharge trench 391.

The second discharge trench 392 may be disposed between the unit area UA and the second corner CR2. The second discharge trench 392 may extend toward the second corner CR2. The second discharge trench 392 may extend in a fifth direction DR5, which is between the first direction DR1 and the second direction DR2. The fifth direction DR5 may be a different direction from the fourth direction DR4.

The second discharge trench 392 may be connected to the second portion 320b of the second trench 320. The second discharge trench 392 may be connected to the second portion 330b of the third trench 330. The second discharge trench 392 may be connected to the second portion 360b of the sixth trench 360. The second discharge trench 392 may be connected to the second portion 370b of the seventh trench 370. A bottom surface of the second discharge trench 392 may be inclined. A depth of the second discharge trench 392 may increase as the second discharge trench 392 extends toward the second corner CR2.

The third discharge trench 393 may be disposed between the unit area UA and the third corner CR3. The third discharge trench 393 may extend toward the third corner CR3. The third discharge trench 393 may extend in the fourth direction DR4.

The third discharge trench 393 may be connected to the first portion 330a of the third trench 330. The third discharge trench 393 may be connected to the first portion 340a of the fourth trench 340. The third discharge trench 393 may be connected to the first portion 370a of the seventh trench 370. The third discharge trench 393 may be connected to the first portion 380a of the eighth trench 380. A bottom surface of the third discharge trench 393 may be inclined. A depth of the third discharge trench 393 may increase as the third discharge trench 393 extends toward the third corner CR3.

The fourth discharge trench 394 may be disposed between the unit area UA and the fourth corner CR4. The fourth discharge trench 394 may extend toward the fourth corner CR4. The fourth discharge trench 394 may extend in the fifth direction DR5.

The fourth discharge trench 394 may be connected to the second portion 310b of the first trench 310. The fourth discharge trench 394 may be connected to the second portion 340b of the fourth trench 340. The fourth discharge trench 394 may be connected to the second portion 350b of the fifth trench 350. The fourth discharge trench 394 may be connected to the second portion 380b of the eighth trench 380. A bottom surface of the fourth discharge trench 394 may be inclined. The depth of the fourth discharge trench 394 may increase as the fourth discharge trench 394 extends toward the fourth corner CR4.

Referring to FIG. 2, the second edge protective layer 270 may include a first sub-edge protective layer 271, a second sub-edge protective layer 272, and a third sub-edge protective layer 273.

The first sub-edge protective layer 271 may be disposed along a perimeter of the unit area UA. The first sub-edge protective layer 271 may be defined by the unit area UA, the trench 300, and the discharge trench 390. For example, the first sub-edge protective layer 271 may be defined by the unit area UA, the first trench 310, the second trench 320, the third trench 330, the fourth trench 340, the first discharge trench 391, the second discharge trench 392, the third discharge trench 393, and the fourth discharge trench 394. For example, the first sub-edge protective layer 271 may be disposed around the scribe lane SL and the plurality of semiconductor chip mounting areas CA.

The second sub-edge protective layer 272 may be disposed between adjacent trenches 300. The second sub-edge protective layer 272 may be disposed between adjacent discharge trenches 390. The second sub-edge protective layer 272 may be defined by the trench 300 and the discharge trench 390. For example, the second sub-edge protective layer 272 may be defined by the first trench 310, the fifth trench 350, the first discharge trench 391, and the fourth discharge trench 394. In another example, the second sub-edge protective layer 272 may be defined by the second trench 320, the sixth trench 360, the first discharge trench 391, and the second discharge trench 392.

The third sub-edge protective layer 273 may be disposed between the edge and the trench 300. The third sub-edge protective layer 273 may be disposed between adjacent discharge trenches 390. The third sub-edge protective layer 273 may be defined by the edge area EA, the trench 300, and the discharge trench 390. For example, the third sub-edge protective layer 273 may be defined by the first edge E1, the fifth trench 350, the first discharge trench 391, and the second discharge trench 392. In example embodiments of the present inventive concept, the third sub-edge protective layer 273 may be defined by the second edge E2, the sixth trench 360, the first discharge trench 391, and the second discharge trench 392.

Next, an effect of the trench 300 will be described with reference to FIG. 6 and FIG. 7.

The semiconductor chip may be mounted on the package substrate and in the semiconductor chip mounting area CA. The semiconductor chip mounted on the package substrate may be molded with a mold material 400. The mold material 400 may include, for example, an epoxy mold compound. The mold material 400 may cover the unit area UA.

In a process of molding the semiconductor chip, the mold material 400 may flow beyond the unit area UA to the edge area EA. The mold material 400 may be received in the trench 300. In example embodiments of the present inventive concept, the mold material 400 may be discharged to the outside through the discharge trench 390. To discharge the mold material 400, the bottom surface of the trench 300 and the bottom surface of the discharge trench 390 may be inclined.

The mold material 400 may be first received in a portion of the trench 300 disposed adjacent to the unit area UA. For example, referring to FIG. 6, the mold material 400 may be received in the first portion 310a of the first trench 310 and the second portion 310b of the first trench 310. The mold material 400 may be received in the first portion 320a of the second trench 320 and the second portion 320b of the second trench 320. The mold material 400 may be received in the first portion 330a of the third trench 330 and the second portion 330b of the third trench 330. The mold material 400 may be received in the first portion 340a of the fourth trench 340 and the second portion 340b of the fourth trench 340.

The discharge trench 390 may discharge the mold material 400 received in the portion of the trench 300 disposed adjacent to the unit area UA to the outside. The first discharge trench 391 may discharge the mold material 400 received in the first portion 310a of the first trench 310 and the first portion 320a of the second trench 320 (refer to a reference numeral Q1). The second discharge trench 392 may discharge the mold material 400 received in the second portion 320b of the second trench 320 and the second portion 330b of the third trench 330 (refer to a reference numeral Q2). The third discharge trench 393 may discharge the mold material 400 received in the first portion 330a of the third trench 330 and the first portion 340a of the fourth trench 340 (refer to a reference numeral Q3). The fourth discharge trench 394 may discharge the mold material 400 received in the second portion 310b of the first trench 310 and the second portion 340b of the fourth trench 340 (refer to a reference numeral Q4).

The mold material 400 may flow beyond a mold receiving range of the trench 300 adjacent to the unit area UA. In this case, the mold material 400 may be received into a portion of the trench 300 disposed far away from the unit area UA.

For example, referring to FIG. 7, the mold material 400 may be received into the first portion 350a of the fifth trench 350 and the second portion 350b of the fifth trench 350. The mold material 400 may be received into the first portion 360a of the sixth trench 360 and the second portion 360b of the sixth trench 360. The mold material 400 may be received into the first portion 370a of the seventh trench 370 and the second portion 370b of the seventh trench 370. The mold material 400 may be received into the first portion 380a of the eighth trench 380 and the second portion 380b of the eighth trench 380.

The discharge trench 390 may discharge the mold material 400 received into the portion of the trench 300 disposed far away from the unit area UA to the outside. The first discharge trench 391 may discharge the mold material 400 received in the first portion 350a of the fifth trench 350 and the first portion 360a of the sixth trench 360 (refer to a reference numeral Q5). The second discharge trench 392 may discharge the mold material 400 received in the second portion 360b of the sixth trench 360 and the second portion 370b of the seventh trench 370 (refer to a reference numeral Q6). The third discharge trench 393 may discharge the mold material 400 received in the first portion 370a of the seventh trench 370 and the first portion 380a of the eighth trench 380 (refer to a reference numeral Q7). The fourth discharge trench 394 may discharge the mold material 400 received in the second portion 350b of the fifth trench 350 and the second portion 380b of the eighth trench 380 (refer to a reference numeral Q8).

When the mold material 400 flows beyond the unit area UA of the package substrate to the edge area EA thereof, a burr may be formed on the first to fourth edges E1 to E4. When the burr is removed from the package substrate and flows into the semiconductor processes apparatus during a subsequent process, it may cause apparatus failure and deteriorate the quality of the semiconductor package.

The mold material 400 flowing into the edge area EA may be received into the trench 300 formed in the edge area EA thereby preventing the formation of the burr in the edge area. Thus, the package substrate that increases the yield and reliability of the semiconductor package may be provided.

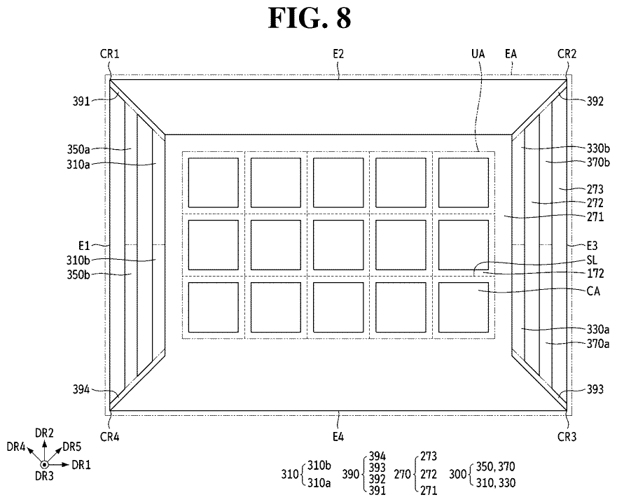

FIG. 8 is a diagram for illustrating a package substrate according to example embodiments of the present inventive concept. For reference, FIG. 8 is a plan view for illustrating a package substrate according to example embodiments of the present inventive concept. For convenience of description, following description focuses on differences thereof from the descriptions as set forth above with reference to FIGS. 1 to 5. To the extent that an element has not been described in detail, it may be assumed that the element is at least similar to corresponding elements that have been described in FIGS. 1 through 5.

Referring to FIG. 8, in example embodiments of the present inventive concept, the trench 300 might not include the second trench 320, the fourth trench 340, the sixth trench 360, and the eighth trench 380.

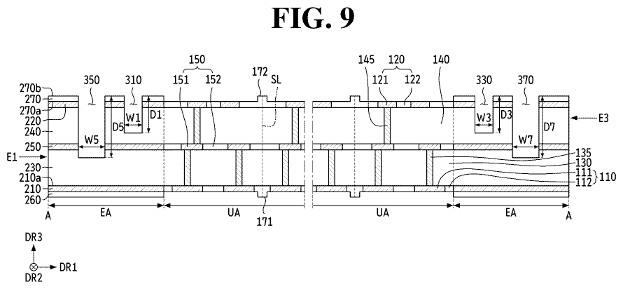

FIG. 9 is a diagram for illustrating a package substrate according to example embodiments of the present inventive concept. For reference, FIG. 9 is a cross-sectional view as taken along a line A-A of FIG. 2. For convenience of description, following description focuses on differences thereof from the descriptions as set forth above with reference to FIGS. 1 to 5. To the extent that an element has not been described in detail, it may be assumed that the element is at least similar to corresponding elements that have been described in FIGS. 1 through 5.

Referring to FIG. 9, in example embodiments of the present inventive concept, the width W1 of the first trench 310 may be smaller than a width W5 of the fifth trench 350. The width W1 of the first trench 310 may be smaller than a width W7 of the seventh trench 370. A width W3 of the third trench 330 may be smaller than the width W5 of the fifth trench 350. The width W3 of the third trench 330 may be smaller than the width W7 of the seventh trench 370.

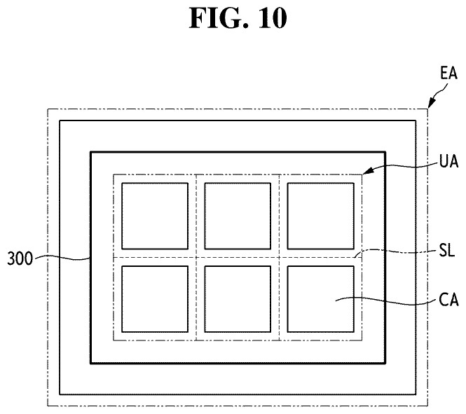

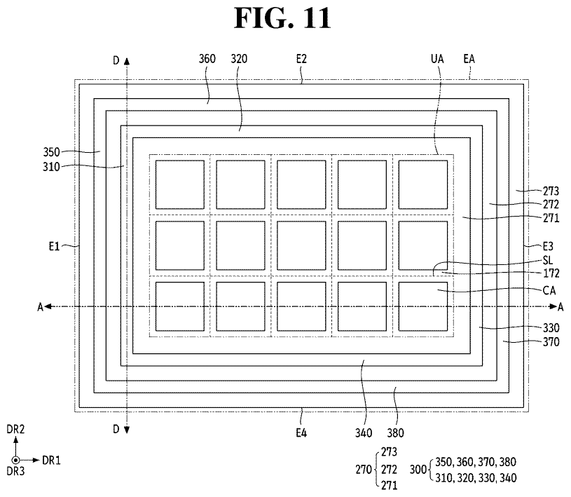

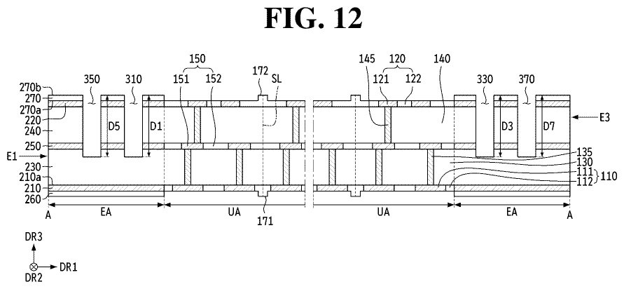

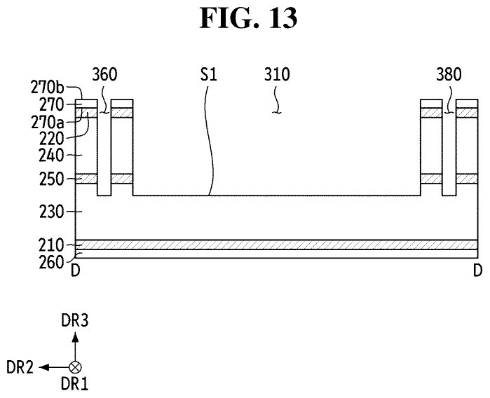

FIGS. 10 to 13 are diagrams for illustrating a package substrate according to example embodiments of the present inventive concept. For reference, FIG. 10 is a schematic conceptual diagram for illustrating a package substrate according to example embodiments of the present inventive concept. FIG. 11 is a plan view of the package substrate of FIG. 10. FIG. 12 is a cross-sectional view as taken along a line A-A of FIG. 10. FIG. 13 is a cross-sectional view as taken along a line D-D of FIG. 12. For convenience of description, following description focuses on differences thereof from the descriptions as set forth above with reference to FIGS. 1 to 5. To the extent that an element has not been described in detail, it may be assumed that the element is at least similar to corresponding elements that have been described in FIGS. 1 through 5.

Referring to FIG. 11, the package substrate according to example embodiments of the present inventive concept might not include the discharge trench 390.

The first trench 310 may be connected to the second trench 320 and the fourth trench 340. The second trench 320 may be connected to the third trench 330. The third trench 330 may be connected to the fourth trench 340.

The fifth trench 350 may be connected to the sixth trench 360 and the seventh trench 370. The sixth trench 360 may be connected to the seventh trench 370. The seventh trench 370 may be connected to the eighth trench 380.

Referring to FIG. 12, the depth D1 of the first trench 310 may be equal to the depth D5 of the fifth trench 350. The depth D1 of the first trench 310 may be equal to the depth D7 of the seventh trench 370. The depth D3 of the third trench 330 may be equal to the depth D5 of the fifth trench 350. The depth D3 of the third trench 330 may be equal to the depth D7 of the seventh trench 370.

Referring to FIG. 13, the bottom surface of the trench 300 might not be inclined. For example, the bottom surface S1 of the first trench 310 may be extend in a parallel manner to the contact surface 210a of the first edge wiring 210.

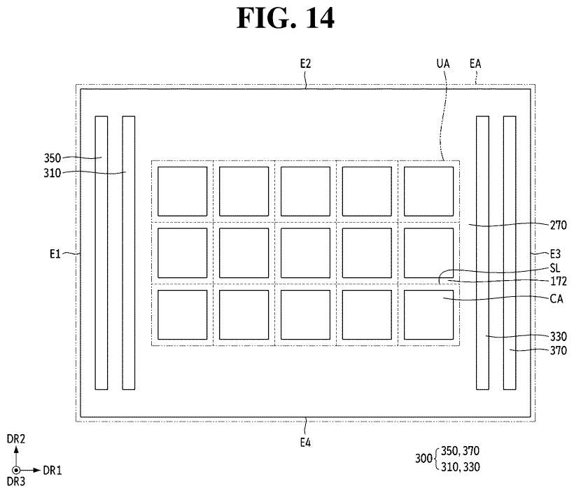

FIG. 14 is a diagram for illustrating a package substrate according to example embodiments of the present inventive concept. For reference, FIG. 14 is a plan view of a package substrate according to example embodiments of the present inventive concept. For convenience of description, following description focuses on differences thereof from the descriptions as set forth above with reference to FIGS. 1 to 5 and FIG. 11. To the extent that an element has not been described in detail, it may be assumed that the element is at least similar to corresponding elements that have been described in FIGS. 1 through 5, and 11.

Referring to FIG. 14, the package substrate according to some embodiments might not include the second trench 320, the fourth trench 340, the sixth trench 360, and the eighth trench 380.

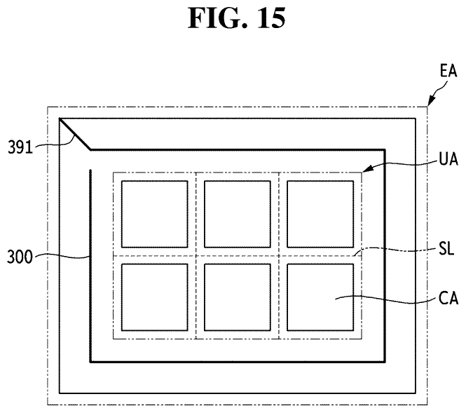

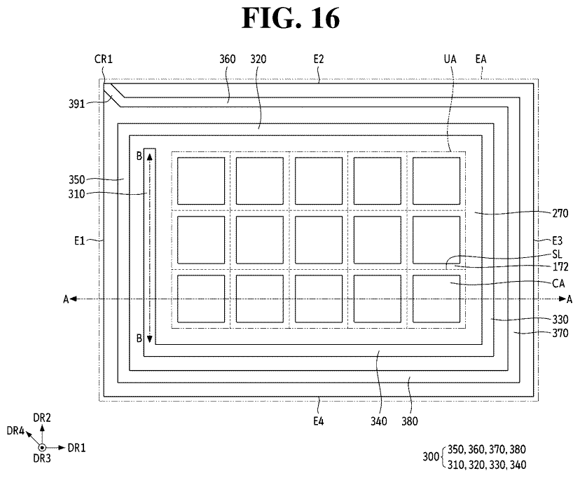

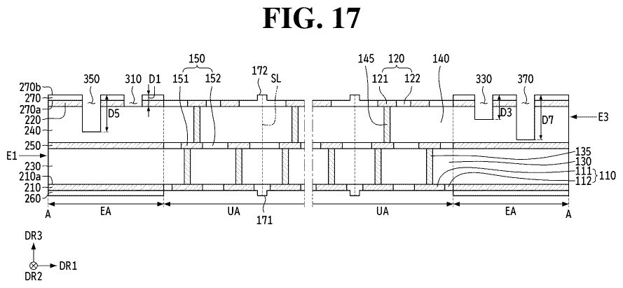

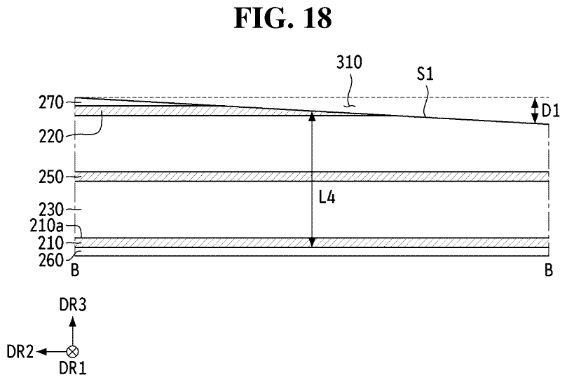

FIGS. 15 to 18 are diagrams for illustrating a package substrate according to example embodiments of the present inventive concept. For reference, FIG. 15 is a schematic conceptual diagram for illustrating the package substrate according to example embodiments of the present inventive concept. FIG. 16 is a plan view of the package substrate of FIG. 15. FIG. 17 is a cross-sectional view as taken along a line A-A of FIG. 16. FIG. 18 is a cross-sectional view as taken along a line B-B of FIG. 16. For convenience of description, following description focuses on differences thereof from the descriptions as set forth above with reference to FIGS. 1 to 5. To the extent that an element has not been described in detail, it may be assumed that the element is at least similar to corresponding elements that have been described in FIGS. 1 through 5.

Referring to FIGS. 15 to 18, the package substrate according to example embodiments of the present inventive concept might not include the second discharge trench 392, the third discharge trench 393, and the fourth discharge trench 394.

The trench 300 may extend along the perimeter of the unit area UA. The trench 300 may be connected to the first discharge trench 391.

The first trench 310 may be connected to the fourth trench 340. The fourth trench 340 may be connected to the third trench 330. The third trench 330 may be connected to the second trench 320. The second trench 320 may be connected to the fifth trench 350. The fifth trench 350 may be connected to the eighth trench 380. The eighth trench 380 may be connected to the seventh trench 370. The seventh trench 370 may be connected to the sixth trench 360. The sixth trench 360 may be connected to the first discharge trench 391.

The depth D1 of the first trench 310 may be smaller than the depth D3 of the third trench 330. The depth D3 of the third trench 330 may be smaller than the depth D5 of the fifth trench 350. The depth D5 of the fifth trench 350 may be smaller than the depth D7 of the seventh trench 370.

The bottom surface of the trench 300 may be inclined. The bottom surface S1 of the first trench 310 may be inclined. The depth D1 of the first trench 310 may increase as it extends toward the fourth edge E4. The fourth distance L4 may decrease as it extends toward the fourth edge E4. The fourth distance L4 refers to a distance from a contact surface 210a of the first edge wiring 210 to the bottom surface S1 of the first trench 310.

The bottom surface of the second trench 320 may be inclined. The depth of the second trench 320 may increase as it extends toward the first edge E1. The bottom surface of the third trench 330 may be inclined. The depth of the third trench 330 may increase as it extends toward the second edge E2. The bottom surface of the fourth trench 340 may be inclined. The depth of the fourth trench 340 may increase as it extends toward the third edge E3.

The bottom surface of the fifth trench 350 may be inclined. The depth of the fifth trench 350 may increase as it extends toward the fourth edge E4. The bottom surface of the sixth trench 360 may be inclined. The depth of the sixth trench 360 may increase as it extends toward the first edge E1. The bottom surface of the seventh trench 370 may be inclined. The depth of the seventh trench 370 may increase as it extends toward the second edge E2. The bottom surface of the eighth trench 380 may be inclined. The depth of the eighth trench 380 may increase as it extends toward the third edge E3.

The bottom surface of the first discharge trench 391 may be inclined. The depth of the first discharge trench 391 may increase as it extends toward the first corner CR1.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A package substrate comprising:
a unit area including a plurality of semiconductor chip mounting areas and a scribe lane disposed between adjacent ones of the semiconductor chip mounting areas;
an edge area surrounding the unit area; and
a trench formed in the edge area, the trench configured to receive a mold material for molding a semiconductor chip to be mounted on the plurality of semiconductor chip mounting areas.

2. The package substrate of claim 1, further comprising a discharge trench formed in the edge area and configured to discharge the mold material received in the trench to an outside of the package substrate,
wherein the edge area includes a first edge, a second edge intersecting the first edge, and a corner at which the first edge and the second edge intersect each other,
wherein the trench includes a first trench disposed between the first edge and the unit area, and extending in a parallel manner to the first edge, wherein the first trench is connected to the discharge trench,
wherein the discharge trench extends from the first trench towards the corner.

3. The package substrate of claim 2, wherein each of a bottom surface of the trench and a bottom surface of the discharge trench is inclined.

4. The package substrate of claim 2, wherein the trench further includes a second trench disposed between the second edge and the unit area and extending in a parallel manner to the second edge, wherein the second trench is connected to the discharge trench.

5. The package substrate of claim 2, wherein the trench further includes a second trench disposed between the first edge and the first trench and extending in a parallel manner to the first edge, wherein the second trench is connected to the discharge trench.

6. The package substrate of claim 5, wherein a depth of the second trench is greater than a depth of the first trench.

7. The package substrate of claim 5, wherein a width of the second trench is greater than a width of the first trench.

8. The package substrate of claim 2, wherein the edge area further includes a fourth edge disposed opposite to the second edge,
wherein the trench further includes a fourth trench disposed between the fourth edge and the unit area, and extending in a parallel manner to the fourth edge, wherein the fourth trench is connected to the first trench.

9. The package substrate of claim 8, wherein the edge area further includes a third edge disposed opposite to the first edge,
wherein the trench further includes:
a third trench disposed between the third edge and the unit area, and extending in a parallel manner to the third edge, wherein the third trench is connected to the fourth trench; and
a second trench disposed between the second edge and the unit area, and extending in a parallel manner to the second edge, wherein the second trench is connected to the third trench.

10. The package substrate of claim 1, wherein the edge area includes a first edge and a third edge disposed opposite to each other,
wherein the trench includes:
a first trench disposed between the first edge and the unit area and extending in a parallel manner to the first edge; and
a third trench disposed between the third edge and the unit area and extending in a parallel manner to the third edge.

11. The package substrate of claim 10, wherein the edge area further includes a second edge intersecting the first edge, and a fourth edge disposed opposite to the second edge,
wherein the trench further includes:
a second trench disposed between the second edge and the unit area and extending in a parallel manner to the second edge, wherein the second trench is connected to the first trench and the third trench; and
a fourth trench disposed between the fourth edge and the unit area and extending in a parallel manner to the fourth edge, wherein the fourth trench is connected to the first trench and the third trench.

12. A package substrate comprising:
a unit area including a plurality of semiconductor chip mounting areas and a scribe lane disposed between adjacent ones of the semiconductor chip mounting areas;
an edge area surrounding the unit area; and
a trench formed in the edge area,
wherein the edge area includes different first and second edges,
wherein the trench includes a first trench disposed between the unit area and the first edge, and a second trench disposed between the unit area and the second edge,
wherein a depth of the second trench is greater than a depth of the first trench.

13. The package substrate of claim 12, wherein a width of the second trench is greater than a width of the first trench.

14. The package substrate of claim 12, wherein the trench further includes a third trench disposed between the first edge and the first trench,
wherein a depth of the third trench is greater than the depth of the second trench.

15. The package substrate of claim 14, wherein the trench further includes a fourth trench disposed between the second edge and the second trench,
wherein a depth of the fourth trench is greater than the depth of the third trench.

16. The package substrate of claim 12, wherein the trench further includes a third trench disposed between the unit area and the second trench,
wherein the depth of the second trench is greater than a depth of the third trench.

17. The package substrate of claim 16, wherein the depth of the first trench is equal to the depth of the third trench.

18. The package substrate of claim 16, wherein the trench further includes a fourth trench disposed between the first edge and the first trench,
wherein a depth of the fourth trench is greater than the depth of the first trench.

19. The package substrate of claim 18, wherein the depth of the second trench is equal to the depth of the fourth trench.

20. A package substrate comprising:
a unit area including a plurality of semiconductor chip mounting areas and a scribe lane disposed between adjacent ones of the semiconductor chip mounting areas;
an edge area surrounding the unit area;
a trench formed in the edge area, and the trench configured to receive a mold material for molding a semiconductor chip to be mounted on the plurality of semiconductor chip mounting areas; and
a discharge trench formed in the edge area and configured to discharge the mold material in the trench to an outside of the package substrate, wherein the discharge trench includes first and second discharge trenches,
wherein the edge area includes a first edge and a third edge disposed opposite to each other, a second edge intersecting the first edge and the third edge, a first corner at which the first edge and the second edge intersect each other, and a second corner at which the second edge and the third edge intersect each other,
wherein the trench includes first and second portions extending in a parallel manner to the first edge, and connected to the discharge trench, wherein the first portion is disposed close to the second edge and the second portion is disposed away from the second edge,
wherein the first discharge trench extends from the first portion of the trench towards the first corner,
wherein the second discharge trench extends from the second portion of the trench towards the second corner,
wherein each of a bottom surface of the trench and a bottom surface of the discharge trench is inclined.
